(19) United States
(12) Patent Application Publication
(10) Pub. No.: US 2007/0229160 A1
(43) Pub. Date: Oct. 4, 2007

(54) Control circuit for controlling a current and/or voltage of an electronic circuit

(75) Inventor: Franz Beck, Schwendi (DE)

Correspondence Address: MCGRATH, GEISSLER, OLDS & RICHARDSON, PLLC, P.O. BOX 1364, FAIRFAX, VA, 22038-1364, US

(73) Assignee: ATMEL GERMANY GMBH

(21) Appl. No.: 11/785,552

(22) Filed: Apr. 18, 2007

Related U.S. Application Data
(63) Continuation of application No. PCT/EP05/10991, filed on Oct. 13, 2005.

(30) Foreign Application Priority Data
Oct. 18, 2004 (DE) DE10 2004.052.214

(51) Int. Cl. H03F 3/45

(52) U.S. Cl. 330/255

(57) ABSTRACT

A control circuit is provided for controlling a current and/or voltage of an electronic circuit. The circuit comprises an input stage, which has at least one input, a supply voltage terminal, an amplifier element, and a subcircuit. The amplifier element comprises an operating current path and a control terminal. In the circuit, the subcircuit applies a bias to the control terminal and the input is connected to the latter. The control circuit is characterized in that the subcircuit provides a bias, which is independent of a supply voltage applied to the supply voltage terminal and of a current amplification of the amplifier element.

This nonprovisional application is a continuation of International Application No. PCT/EP2005/010991, which was filed on Oct. 13, 2005, and which claims priority to German Patent Application No. DE 102004052214, which was filed in Germany on Oct. 18, 2005, and which are both herein incorporated by reference.

### BACKGROUND OF THE INVENTION

1. Field of the Invention

The present invention relates to a control circuit for controlling a current and/or voltage of an electronic circuit, with an input stage, which has at least one input, a supply voltage terminal, an amplifier element, and a subcircuit; in the circuit. The amplifier element has an operating current path and a control terminal, the subcircuit applies a bias to the control terminal, and the input is connected to the control terminal.

2. Description of the Background Art

In the following, the term bias (bias voltage) may describe a DC voltage which is derived from the supply voltage and is generated to set the operating point in the absence of an input signal.

Control circuits of this type are employed, for example, for switching of current sources of a laser driver of a write channel or read channel in DVD devices with so-called single-ended control signals. Examples of single-ended signals are CMOS, CTL, and RS-422 signals.

In prior-art control circuits, unwanted variations occur in the values of the control circuit output signals between different specimens of integrated control circuits, which originate from the same production run.

### SUMMARY OF THE INVENTION

It is therefore an object of the present invention to provide an improved control circuit with reduced production-related variations.

This object is achieved in a control circuit in that the bias is independent of a supply voltage applied to the supply voltage terminal and of a current amplification of the amplifier element.

The invention is based on the following insights: Prior-art control circuits have a bipolar transistor, connected as an emitter follower, as the amplifier element, in which the bias is supplied by an in-circuit voltage source. The voltage source is connected via a large resistor to the bipolar transistor base, serving as the control terminal, so that the bias forms as the product of the value of the series resistor and the bipolar transistor base current flowing across the series resistor. The emitter followers have a current amplification, which, as is known, is defined as the ratio of the collector current to the base current.

Production-related variations in the current amplification are reflected in variations in base currents and thereby in variations in bias voltages, and this has an undesirable effect on the operating point and thereby on the output signal of the control circuit. Because the current, which flows over the operating current path of the emitter follower, is a function of the supply voltage, production related variations in the supply voltage are reflected via the collector current and the current amplification in the base current and thereby also in variations in the bias.

The cause of the unwanted variations is eliminated by the provision, according to the invention, of a bias, which is independent both of a supply voltage applied to the supply voltage terminal and a current amplification of the amplifier element.

An embodiment provides that the subcircuit has a current source, a first transistor, a current mirror, a first series connection comprising a first resistor, an operating current path of a second transistor, connected as a diode, and a second resistor, a second series connection comprising operating current paths of a third transistor and of a fourth transistor, as well as a third resistor that has the same value as the second resistor, and a fifth resistor, the current source being connected to the supply potential terminal; the embodiment provides furthermore that the first transistor divides a current, supplied by the current source, into a base current and a collector current, the first series connection lies between a first node, which takes up the collector current, and the reference potential terminal, the second series connection lies between the supply potential terminal and the reference potential terminal, the second, third, and fourth transistors are the same, a base of the third transistor is connected to the first node and together with the current mirror draws the n-fold value of the base current from the first node, a second node, lying between the third and fourth transistor, is connected to the input via a series resistor and an input signal resistor, a third node, lying between a series resistor and an input signal resistor, is connected to the control terminal of the amplifier element, an operating current path of the amplifier element conducts an m-fold value of the collector current of the first transistor and a value of the series resistor is the n+1-fold value of the m-th part of the sum of the values of the first resistor and second resistor.

These special circuit design measures produce a bias, at which both the base current of the amplifier elements and the effects of the supply voltage are automatically and fully compensated. The compensation of the base current of the amplifier elements simultaneously achieves a limitation of the output signal level from the input stage. In this way, different input signal levels can also be processed without a circuit design adjustment needing to be made to individual input signals.

The input stage can have at least one additional input and an additional amplifier element with an additional operating current path and an additional control terminal and that the second node, lying between the third and the fourth transistor, is connected to the input via an additional series resistor and an additional input signal resistor, a fourth node, lying between the additional series resistor and the additional input signal resistor, is connected to the additional control terminal of the additional amplifier element, an operating current path of the additional amplifier element conducts an m-fold value of the collector current of the first transistor, and the additional series resistor has the n+1-fold value of the m-th part of the sum of the values of the first resistor and second resistor.

As an alternative to the aforementioned single-ended control signals, for example, differential signals (LVDS, LVDECL) with a broad offset voltage range are also employed frequently for switching of current sources of a laser driver of a write channel or read channel in DVD devices. Different input stages are normally necessary for this. The aforementioned embodiment has the special advantage that both single-ended signals and differential signals can be processed without changes to the circuit, without an external capacitance needing to be applied for blocking at a then free input during the processing of single-ended signals.

Another embodiment includes a driver stage, which receives at least one output signal of the amplifier element as a driver stage input signal and amplifies it via an input of a differential amplifier.

The differential amplifier in the case of a supply with a single-ended signal causes a conversion of the single-ended signal into a differential signal. One of the two control terminals of the differential amplifier can be simply left open.

Furthermore, the driver stage can receive a first output signal from a first amplifier element and another output signal from an additional amplifier element as driver stage input signals and amplifies the first output signal via a first input of a differential amplifier and amplifies the additional output signal via an additional input of the differential amplifier.

By means of this embodiment, the differential amplifier can be used to amplify differential signals and single-ended signals, so that not only the input stage but also the driver stage can process both single-ended signals and differential signals without changes in the circuit design.

Within the scope of another embodiment, the driver stage can have a quad switch, which provides a differential output signal of the differential amplifier for a first output branch of the driver stage and/or for an additional output branch of the driver stage.

In this way, the differential signal can be fed optionally to the first output branch and/or the second output branch.

Also, at least one output branch of the driver stage can have a complementary emitter follower.

Complementary emitter followers are notable for a high output power. For the case when the control circuit controls the current switch with a low input resistance and thereby a high power requirement, which may be the case, for example, at high write speeds in DVD devices, this embodiment provides sufficiently high driver currents to control the current switch.

The driver stage can be supplied with at least one control current, which depends on the current and/or voltage signal of the electronic circuit, and that the driver stage changes the output signals of the driver stage as a function of the control current.

In DVD devices, the waveform of a switched output current is important. Particularly the rising and falling edges must be sufficiently steep and the transient is limited by the narrow limits. In DVD devices, the output signals of the driver stage exert a major effect on the waveform, whereby the optimal value of the output signals depends on the value of the current to be switched. By supplying the control current, which depends on the current and/or voltage signal of the electronic circuit, and by changing the output signals of the driver stage as a function of the control current, the required waveform can be generated for a broad range of values for currents to be switched.

Another embodiment provides that the driver stage can be supplied with a first control current and a second control current and that the first control current is added via a current mirror to a current supplying the differential amplifier.

Output signals of the differential amplifier are changed on the input side of the driver stage by this embodiment.

The second control current can control a current supplying the emitter followers.

Output signals of the driver stage are changed on the output side of the driver stage by these embodiments.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates an overall view of an example of an electronic circuit to be controlled, together with a control circuit with an input stage and an output stage;

FIG. 2 illustrates a circuit diagram of an input stage with examples of elements of the invention;

FIG. 3 illustrates a circuit diagram of a driver stage with examples of elements of the invention; and

FIG. 4 illustrates output signals of the control circuit as a function of a control current.

### DETAILED DESCRIPTION

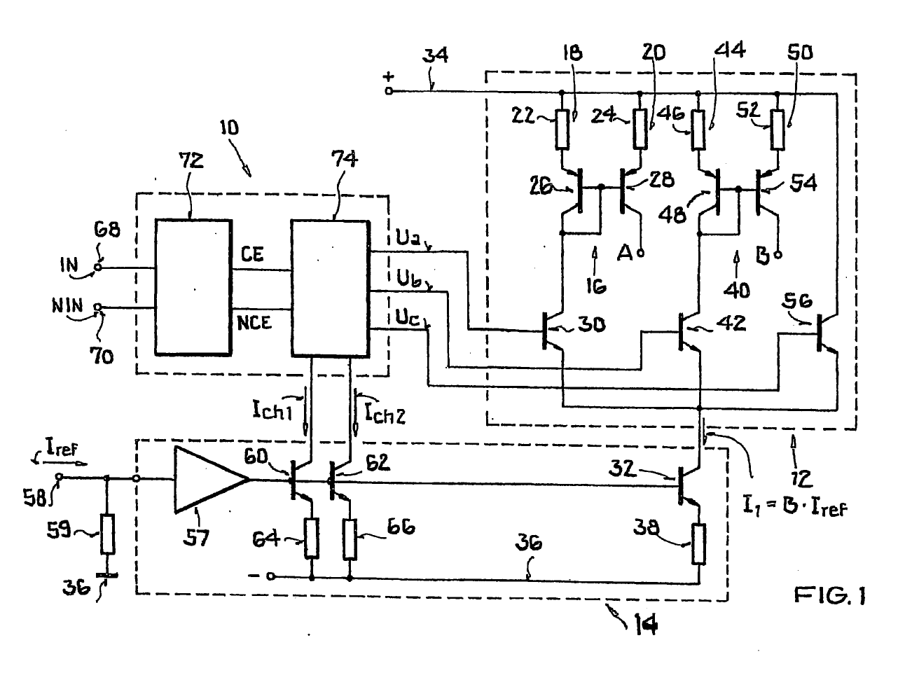

FIG. 1 shows a control circuit 10 together with an electronic circuit 12 to be controlled and a circuit 14, which supplies a base value of an output current of circuit 12. Circuit 12 has an output A and an output B, whereby outputs A, B, for example, can be assigned to read channels or write channels of a DVD device.

Output A is supplied from a current mirror 16, which has a control branch 18 and a power branch 20. Each of the branches 18, 20 has an ohmic resistor 22, 24 and a transistor 26, 28, whereby transistor 26 of control branch 18 is connected as a diode. Control branch 18, together with an operating current path of a first output transistor 30 and a control current transistor 32, lies in series between a supply potential 34 and a reference potential 36. Moreover, an ohmic resistor 38 can be integrated into this series connection. A second current mirror 40 supplies output B and is controlled by a second output transistor 42. Current mirror 40 is designed like current mirror 16 and therefore has a control branch 44 with an ohmic resistor 46 and a transistor diode 48, as well as a power branch 50 with an ohmic resistor 52 and a transistor 54.

A third output transistor 56 lies parallel to current mirrors 16 and 40 between supply potential 34 and control current transistor 32. Control circuit 10 outputs three control signals Ua, Ub, and Uc, whereby Ua controls first output transistor 30, Ub controls second output transistor 42, and Uc controls third output transistor 56. Output transistors 30, 42 and 56 are examples of the aforementioned current switches. The output current at output A depends on the difference of the voltages Ua and Uc. Analogously, the output current at output B depends on the difference of the voltages Ub and Uc. The base values of the output current at output A and the output current at output B are set with the use of control current transistor 32. For this purpose, a control signal is supplied to circuit 14 via a terminal 58 and amplified with an amplifier 57 by a factor B. The control signal is, for example, the voltage drop of a control current base value Iref across a resistor 59. A current I1, which is greater than Iref by an amplification factor B, then flows across control current transistor 32.

As already mentioned, in DVD devices the waveform of the switched output current is important. The voltages Ua, Ub, and Uc and the voltage differences Ua−Uc for output A and Ub−Uc for output B have a substantial effect on the waveform. Their optimal value depends on the magnitude of the control current Iref or on the magnitude of the output current at output A and/or output B. Control circuit 10 is designed such that the voltages Ua, Ub, and Uc are set depending on the set output current. With the aid of transistors 60 and 62, control currents Ich1 and Ich2 are generated proportional to the control current base value Iref and supplied to control circuit 10. For this purpose, the conductivity paths of transistors 60 and 62 are each switched with a resistor 64, 66 between reference potential 36 and the inputs of control circuit 10, whereby control terminals of transistors 60, 62 are controlled by amplifier 57 as a function of the control current base value Iref.

Control circuit 10 has two inputs 68 and 70, via which the input signals IN and/or NIN of an input stage 72 of control circuit 10 can be supplied. Input stage 72 forms signals CE and NCE therefrom, which are supplied to a driver stage 74. From these signals CE and NCE and control currents Ich1 and Ich2, the driver stage forms the control voltages Ua, Ub, and Uc.

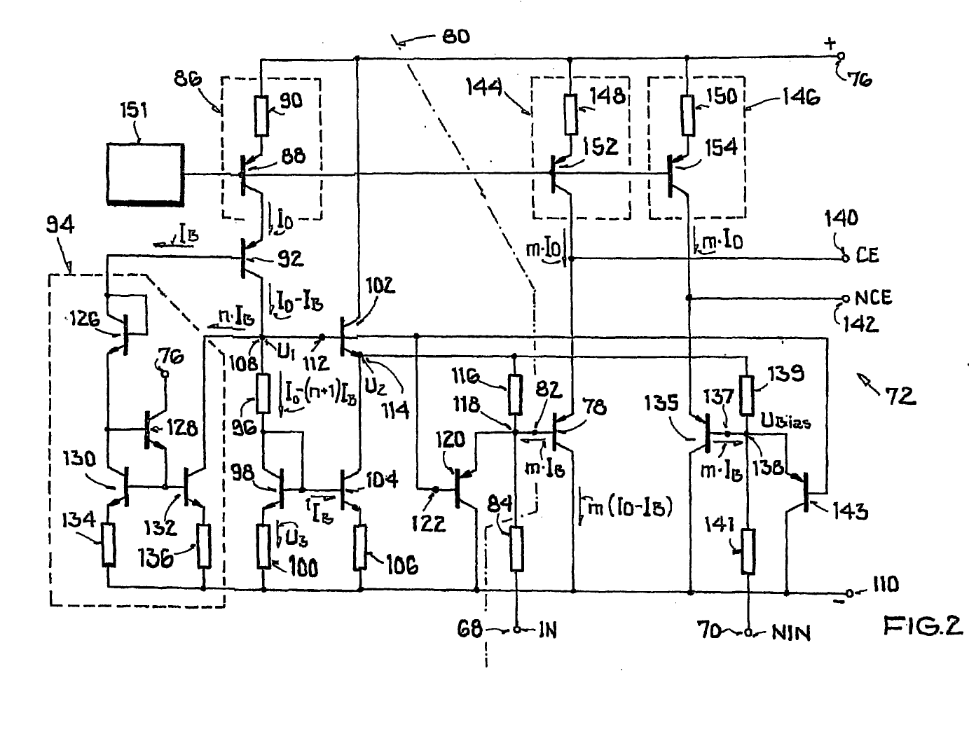

FIG. 2 shows a circuit diagram of an input stage 72, which has inputs 68 and 70, a supply voltage terminal 76, an amplifier element 78, and a subcircuit 80, whereby amplifier element 78 has an operating current path and a control terminal 82 and whereby subcircuit 80 applies a bias Ubias to control terminal 82 and whereby an input 68 is connected to the control terminal via an input signal resistor 84. The bias provided by subcircuit 80 is dependent both on a supply voltage applied to supply voltage terminal 76 and on a current amplification of amplifier element 78. Instead of two inputs 68, 70, the input stage can also have only one input 68, to process single-ended signals.

Subcircuit 80 has a current source 86 comprising a transistor 88 and a resistor 90, a first transistor 92, a current mirror 94, a first series connection comprising a first resistor 96, an operating current path of a second transistor 98, connected as a diode, and a second resistor 100, a second series connection comprising operating current paths of a third transistor 102 and of a fourth transistor 104, as well as a third resistor 106 that has the same value as second resistor 100. Current source 86 is connected to the supply potential terminal 76. First transistor 92 divides a current I0 supplied by current source 86 into a base current IB and a collector current I0-IB. The first series connection lies between a first node 108, which takes up the collector current I0-IB, and a reference potential terminal 110.

The second series connection lies between supply potential terminal 76 and reference potential terminal 110. Second transistor 98 has the same properties as third transistor 102 and fourth transistor 104. A base 112 of third transistor 102 is connected to first node 108 and draws, together with current mirror 94, the n-fold value of the base current IB of first node 108. A second node 114, lying between third transistor 102 and fourth transistor 104, is connected to input 68 via a series resistor 116 and input signal resistor 84, whereby a third node 118, lying between series resistor 116 and input signal resistor 84, is connected to control terminal 82 of amplifier element 78. An operating current path of amplifier element 78 conducts an m-fold value of the collector current I0-IB of first transistor 92. Series resistor 116 has the n+1-fold value of the m-th part of the sum of the values of first resistor 96 and second resistor 100. An operating current path of a fifth transistor 120 lies between third node 118 and reference potential terminal 110. A control terminal 122 of fifth transistor 120 is connected to base 112 of third transistor 102.

As mentioned previously, the base of amplifier element 78 in prior-art control circuits is connected via a large resistor to an internal voltage source. A change in the current amplification of amplifier element 78 then causes a perceptible change in the bias Ubias at third node 118 via the change in the base current.

With the proposed circuit, the bias at third node 118 becomes independent of the supply voltage at supply voltage terminal 76 and the current amplification of amplifier element 78. This results from the following relationships.

Current source 86 supplies the current I0. First transistor 92 has a corresponding base current IB which is increased with current mirror 94 with a current transformation n to n*IB and is subtracted at first node 108. Current mirror 94 includes, for example, transistors 126, 128, 130, 132 and resistors 134, 136, which are connected in the shown manner. For a voltage U1 at first node 108, the following then applies:
U1=(I0−(n+1)IB)R0+UBE+(I0−(n+2)IB)R1,

where R0 is the value of first resistor 96, R1 the value of third resistor 100, and UBE the base-emitter voltage of third transistor 102.

Because transistors 98, 102, and 104 according to the assumption are the same, the following applies to the voltage U2 at second node 114:

$$\begin{matrix}U 2 = U 1 - UBE \\ = ( I 0 - ( n + 1 ) IB ) R 0 + ( I 0 - ( n + 2 ) IB ) R 1 \\ = I 0 ( R 0 + R 1 ) - IBR 1 - ( n + 1 ) ( R 0 + R 1 ) Ib\end{matrix}$$

When first transistor 92 has the same properties as amplifier element 78, which is realized as a single transistor in FIG. 2, a current source 144 supplies the current m*I0, and input 68 is open, the following then applies for the bias Ubias at third node 118:

$$\begin{matrix}Ubias = U 2 + m Rbias IB \\ = I 0 ( R 0 + R 1 ) - ( n + 1 ) ( R 0 + R 1 ) IB + m Rbias IB\end{matrix}$$

In this case, Rbias is the value of series resistor 116 and is dimensioned so that
Ubias=((n+1)/m)(R0+R1). Then
Ubias=I0 (R0+R1) and thereby as desired independent of the supply voltage and the current amplification.

In an embodiment, input stage 72 has an additional input 70 and an additional amplifier element 135 with an additional operating current path and an additional control terminal 137, whereby second node 114, lying between third transistor 102 and fourth transistor 104, is connected via an additional series resistor 139 and an additional input signal resistor 141 to additional input 70. A fourth node 138, lying between additional series resistor 139 and additional input signal resistor 141, is connected to additional control terminal 137 of additional amplifier element 135. An operating current path of additional amplifier element 135 conducts an m-fold value of collector current I0-IB of first transistor 92, and additional series resistor 139 has the n+1-fold value of the m-th part of the sum of the values of first resistor 96 and second resistor 100. A transistor 143 represents for second input 70 the equivalent of fifth transistor 122 of first input 68.

This type of input stage 72 with a built-in bias generation and level limitation is suitable both for differential input signals such as LVDS, LNPECL within a broad offset voltage range (from 0 V to 2.5 V) and for single-ended signals such as CMOS, TTL, and RS-422. In this case, an external capacitance at the open input for blocking is not necessary. The output signals CE and/or NCE are passed to the subsequent driver stage 74 via terminals 140 and 142. Terminals 140 and 142 are connected via current sources 144 and 146 to supply potential terminal 76. They are designed like current source 86 with one resistor 148, 150 and one transistor 152, 154 and supply a current m*I0. Current sources 144 and 146 are controlled together with current source 86 of a control current source 151.

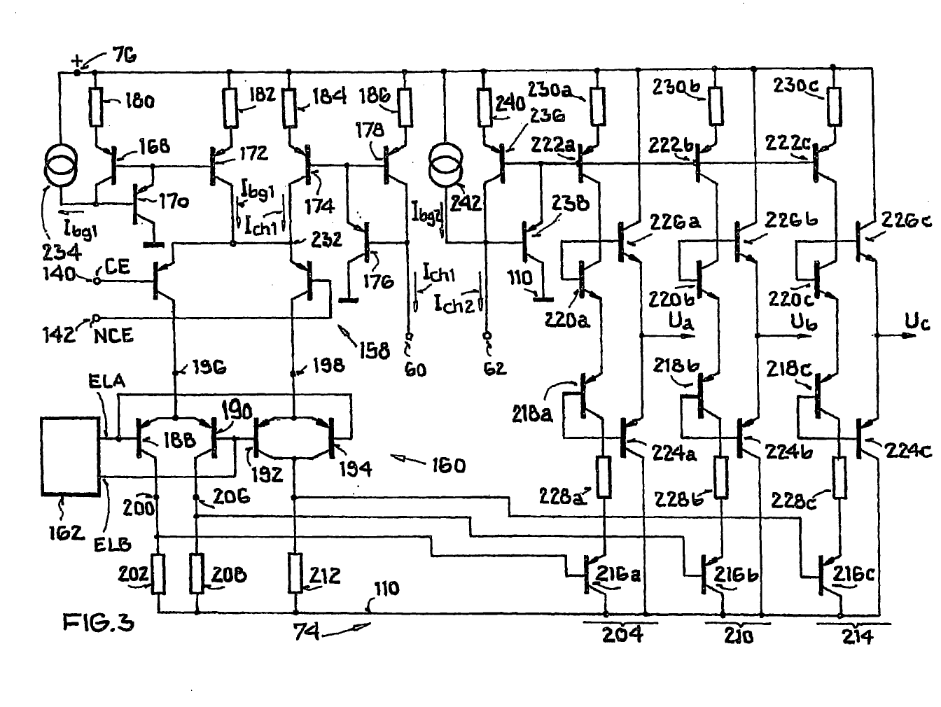

Driver stage 74 will be explained below with reference to FIG. 3. The signals CE and/or NCE are routed via a differential amplifier 158 to a quad switch 160, which is actuated by a control 162. Differential amplifier 158 has two transistors 164, 166, which are connected via additional transistors 168, 170, . . . , 178 and resistors 180, 182, . . . , 186 to a supply potential 76 and whose control terminals are connected to terminals 140, 142 of input stage 72. The output signal CE and/or NCE of input stage 72 is thereby converted via differential amplifier 158 into a differential signal. The subsequent quad switch 160 causes the switching of the input signal to the current switch of outputs A or B of FIG. 1.

Quad switch 60 has a first pair of transistors 188, 190 and a second pair of transistors 192, 194. The emitters of transistors 188, 190 of the first pair are connected to one another and to a first output 196 of differential amplifier 158. Analogously, emitters of transistors 192, 194 of the second pair are connected to one another and to a second output 198 of differential amplifier 158. A first transistor 188 of the first pair is controlled, together with a second transistor 194 of the second pair, by a signal ELA of control 162 and a second transistor 190 of the first pair is controlled, together with a first transistor 192 of the second pair, by a signal ELB of control 162. An output 200 of first transistor 188 of the first pair is connected via a resistor 202 to a reference potential 110 and controls a first complementary emitter follower 204, which supplies the output signal Ua. An output 206 of second transistor 190 of the first pair of transistors is also connected via a resistor 208 to reference potential 110 and controls a second complementary emitter follower 210, which supplies the output signal Ub. Outputs of transistors 192, 194 of the second pair of transistors are connected to one another and via a resistor 212 to reference potential 110. They control a third complementary emitter follower 214, which supplies the output signal Uc. Complementary emitter followers 204, 210, 214 are capable, for example, of driving relatively high base currents of output transistors 30, 42, and 56 of FIG. 1 at high write currents of a DVD device.

The three complementary emitter followers 204, 210, 214 are similarly made of transistors 216a, 218a, . . . , 226a; 216b, 218b, . . . , 226b; 216c, 218c, . . . , 226c and resistors 228a, 230a; 228b, 230b; 228c, 230c and see to it that the output signals Ua, Ub, and Uc are defined either by supply potential 76 or, however, by reference potential 110.

Driver stage 74 thus amplifies at least one output signal CE, NCE of amplifier element 78, 130 of FIG. 2 via an input of differential amplifier 158 and provides via quad switch 160 a differential output signal for a first output branch of driver stage 74 and/or for an additional output branch of driver stage 74, whereby an output branch in each case has a complementary emitter follower 204, 210, 214.

The switched current at outputs A or B in FIG. 1 is variable within the scope of a special circuit design embodiment within a current range of from 0 to about 500 mA and should show short rise and fall times (<1 nsec) and minimal overshoot (<5%) for the entire current range. It is necessary for this that the offset voltage and the amplitude of control signals Ua, Ub, Uc for output transistors 30, 42, and 56 in FIG. 1 are variable and proportional to the control current base value Iref.

In the embodiment shown in FIG. 3, driver stage 74 is supplied with control currents Ich1 and Ich2, which depend on the current Iref of electronic circuit 14 of FIG. 1. Driver stage 74 changes its output signals Ua, Ub, Uc depending on these control currents Ich1, Ich2. For this purpose, a first control current Ich1 is added via a current mirror of transistors 174, 178 at a node 232 to a constant cross current Ibg1, supplying differential amplifier 158, of a constant current source 234. The voltage drop at resistors 202, 208, 212 and thereby the voltage difference (Ua−Uc) or (Ub−Uc) are then proportional to Iref and thereby also proportional to the output current at output A and/or at output B in FIG. 1.

A second control current Ich2, via additional current mirrors comprising transistors 236, 238 and a resistor 240 in a control branch and one of the power branches of transistor 222a and resistor 230a or transistor 222b and resistor 230b or transistor 222c and resistor 230c, controls a current supplying emitter followers 204, 210, 214, so that current Ich2 increases the output signals Ua, Ub, Uc proportional to the output current at outputs A and/or B.

To this end, current Ich2 is added to the constant current Ibg2 of a constant current source 242. The increasing voltage drop across resistors 228a, 228b, and 228c then causes the increase in the signals Ua, Ub, Uc with an increasing output current at outputs A and/or B in FIG. 1. Changing the control voltages Ua, Ub, Uc and the differences (Ua−Uc, Ub−Uc) at output transistors 30, 42 and 56 in FIG. 1 with the value of the output current achieves that the waveform of the output current at outputs A and/or B of electronic circuit 12 of FIG. 1 is maintained over the entire value range of the output current.

By means of control current transistor 32 in FIG. 1, a base value for the output current of the specific channel (A and/or B) is set simultaneously with the control current Iref.

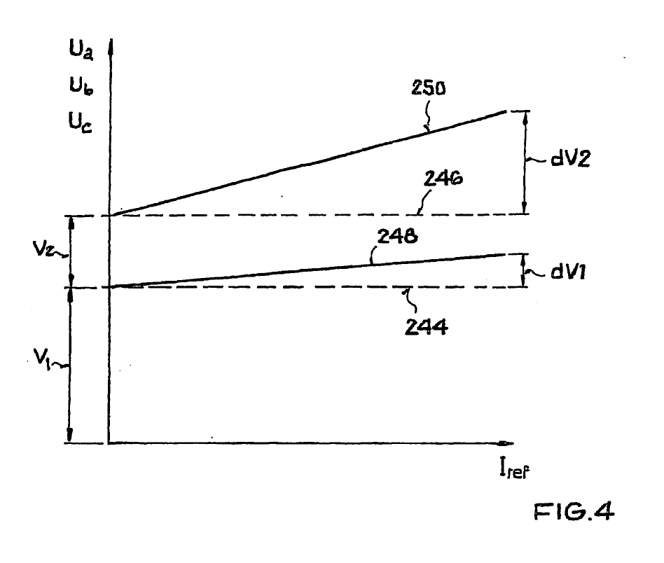

FIG. 4 shows a schematic diagram of the base potentials Ua, Ub, Uc as a function of the control current Iref. The broken line shows a base value of a low level V1 of the signals Ua, Ub, or Uc, which in the discussed circuit assumes a value
V1=Ibg2*(value of the resistor 228a, 228b, or 228c)+2 UBE.

Analogously, the broken line 246 shows a base value of a high level V2 of the signals Ua, Ub, or Uc, which results from the presented circuit as
V2=Ibg1*(value of the resistor 202, 208, or 212).

The solid lines 248 and 250 indicate how V1 and V2 changes in the shown circuit as a function of the control current base value Iref. In this case, d_V1 is calculated to be
d_{—}V1=Ich2*(value of the resistor 228a, 228b, or 228c) and d_{—}V2 to be i_{—}V2=Ich1*(resistor value 202, 208, 212)+Ich2*(resistor value 228a, 228b, 228c).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A control circuit for controlling a current and/or voltage of an electronic circuit, the control circuit comprising an input stage that has at least one input, a supply voltage terminal, an amplifier element, and a subcircuit, in which the amplifier element has an operating current path and a control terminal, in which the subcircuit applies a bias to the control terminal, and in which the input is operatively connected to the control terminal,
wherein the subcircuit provides a bias, which is independent of a supply voltage applied at the supply voltage terminal and of a current amplification of the amplifier element.

2. The control circuit according to claim 1, wherein the subcircuit comprises a current source, a first transistor, a current mirror, a first series connection comprising a first resistor, an operating current path of a second transistor connected as a diode, and a second resistor, a second series connection comprising operating current paths of a third transistor and a fourth transistor, a third resistor that has the same value as the second resistor, and a fifth transistor, wherein the current source is operatively connected to the supply potential terminal, the first transistor divides a current supplied by the current source into a base current and a collector current, the first series connection lies between a first node, which takes up the collector current and a reference potential terminal, the second series connection lies between the supply potential terminal and the reference potential terminal, the second, third and fourth transistor are substantially similar, a base of the third transistor is operatively connected to the first node and together with the current mirror draws the n-fold value of the base current from the first node, a second node, lying between the third and fourth transistor is operatively connected to the reference potential terminal via a series resistor and an input signal resistor, wherein a third node provided between series resistor and input signal resistor is operatively connected to the control terminal of the amplifier element, wherein an operating current path of the amplifier element conducts an m-fold value of the collector current of the first transistor, the series resistor has a n+1-fold value of the m-th part of the sum of the values of the first resistor and second resistor, an operating current path of the fifth transistor is provided between the third node and the reference potential terminal, and wherein a control terminal of the fifth transistor is connected to the base of the third transistor.

3. The control circuit according to claim 2, wherein the input stage has at least one additional input and an additional amplifier element with an additional operating current path and an additional control terminal, and wherein the second node provided between a third and fourth transistor is operatively connected via an additional series resistor and an additional input signal resistor to the input, wherein a fourth node provided between the additional series resistor and the additional input signal resistor is operatively connected to the additional control terminal of the additional amplifier element, wherein an operating current path of the additional amplifier element conducts an m-fold value of the collector current of the first transistor, and wherein the additional series resistor has the n+1-fold value of the m-th part of the sum of the values of the first resistor and second resistor.

4. The control circuit according to claim 1, further comprising a driver stage, which receives at least one output signal of the amplifier element as the driver stage input signal and amplifies it via an input of a differential amplifier.

5. The control circuit according to claim 4, wherein the driver stage receives a first and an additional output signal of the amplifier element as driver stage input signals and amplifies the first output signal via a first input of a differential amplifier and amplifies the additional output signal via an additional input of the differential amplifier.

6. The control circuit according to claim 4, further comprising a quad switch, which provides a differential output signal of the differential amplifier for a first output branch of the driver stage and/or for an additional output branch of the driver stage.

7. The control circuit according to claim 6, wherein the at least one output branch of the driver stage has a complementary emitter follower.

8. The control circuit according to claim 7, wherein the driver stage is supplied with at least one control current, which depends on the current and/or voltage signal of the electronic circuit, and that the driver stage changes the output signals of the driver stage as a function of the control current.

9. The control circuit according to claim 8, wherein the driver stage is supplied with a first control current and a second control current and wherein the first control current is added via a current mirror to a current supplying the differential amplifier.

10. The control circuit according to claim 8, wherein the second control current controls a current supplying the emitter followers.
